(19) United States
(12) Patent Application Publication
(10) Pub. No.: US 2025/0327625 A1
(43) Pub. Date: Oct. 23, 2025

(54) CONCENTRIC TUBE HEAT CARRY-AWAY DEVICE

(71) Applicant: Winconn Systems INC., Taipei City (TW)

(72) Inventor: Jun LIN, Taipei City (TW)

(21) Appl. No.: 18/772,273

(22) Filed: Jul. 15, 2024

(30) Foreign Application Priority Data
Apr. 22, 2024 (CN) 202410486139.5

(51) Int. Cl. F28D 7/12; F28D 7/10; F28F 13/06

(52) U.S. Cl. CPC F28D 7/12; F28D 7/106; F28F 13/06

(57) ABSTRACT

A concentric tube heat carry-away device includes an outer tube, a tube end fixing cap, and an inner tube. Heat dissipation grooves are arranged inside the outer tube, and the heat dissipation grooves form heat-dissipating channels. The inner tube and the outer tube are arranged to space from each other and form a cooling space. The heat-dissipating channels are arranged in the cooling space. The inner tube is in communication with the cooling space. In the concentric tube heat carry-away device, heat enters through the inner tube and heat is transmitted to the inner tube. An inner tube lead-in end of the inner tube is of a horn shape to accelerate entry of the heat. Afterwards, the heat flows from the inner tube back into the outer tube, and heat is further transmitted to the outer tube. The heat dissipation grooves inside the outer tube accelerates dissipation of heat.

### BACKGROUND OF THE INVENTION

### (a) Technical Field of the Invention

The present invention relates to the technical field of heat-dissipating accessories, and more particularly to a concentric tube heat carry-away device.

### (b) Description of the Prior Art

As the performance of various communication and industrial electronic products improves, the power of chips becomes larger and larger, and heat flow density becomes higher and higher, requiring dissipation of heat in order to ensure the release of the chip performance. With the performance heightened, the amount of heat induced by the chips gets larger, so that heat-dissipating devices play an important role in the electronic products. A known heat-dissipating device uses heat dissipation plates carry out heat exchange, yet the heat dissipation performance is poor and the normal operation of the chips may still be affected.

### SUMMARY OF THE INVENTION

An objective of the present invention is to provide a concentric tube heat carry-away device, aiming to resolve the technical issues of use that the heat dissipation performance of the prior art is poor and the normal operation of chips is affected.

To achieve the above objective, an embodiment of the present invention provides a concentric tube heat carry-away device, which comprises an outer tube, tube end fixing cap, and an inner tube, wherein the outer tube, the tube end fixing cap, and the inner tube are sequentially arranged, and centers of the outer tube and the inner tube are on a same straight line, heat dissipation grooves being arranged inside the outer tube, the heat dissipation grooves forming heat-dissipating channels, the tube end fixing cap being arranged inside the outer tube and connected to the outer tube, the tube end fixing cap and the outer tube being arranged to space from each other, the inner tube being arranged inside the tube end fixing cap and penetrating into the tube end fixing cap, the inner tube and the outer tube being arranged to space from each other and forming a cooling space, the heat-dissipating channels being arranged in the cooling space, the inner tube being in communication with the cooling space.

As an optional solution of the present invention, the outer tube comprises an outer tube body and an outer tube flow-return cap, the outer tube body and the outer tube flow-return cap being fixedly connected, the outer tube flow-return cap being arranged in a spherical form.

As an optional solution of the present invention, the heat dissipation grooves are arranged as plural ones, and the plural heat dissipation grooves are uniformly arranged inside the outer tube, the heat dissipation grooves being sequentially connected and laid to completely cover the outer tube, the heat dissipation grooves being of an arc form.

As an optional solution of the present invention, the plural heat dissipation grooves for plural heat-dissipating channels, and the heat-dissipating channels are all in communication with the cooling space.

As an optional solution of the present invention, the tube end fixing cap is formed with positioning notches, and the inner tube penetrates into and is fixed in the positioning notches.

As an optional solution of the present invention, the inner tube comprises an inner tube body, positioning strips, and an inner tube lead-in end, a diameter of the inner tube body being smaller than the outer tube body, the inner tube body being fixedly connected to the positioning strips and the inner tube lead-in end, the positioning strips being arranged as plural ones, the positioning notches corresponding, in number, to the positioning strips, the positioning strips penetrating into and being fixed in the positioning notches.

As an optional solution of the present invention, the inner tube lead-in end is of a horn shape, one end of the inner tube lead-in end being disposed inside the outer tube body and fixedly connected to the inner tube body, an opposite end extending out of the outer tube body.

As an optional solution of the present invention, the inner tube lead-in end and the outer tube body are arranged to space from each other and form a flow conducting space, the flow conducting space being in communication with the cooling space.

As an optional solution of the present invention, materials of the outer tube, the tube end fixing cap, and the inner tube are all copper.

One or multiple technical solutions of the concentric tube heat carry-away device provided in the embodiment of the present invention at least has one of the following technical effects:

The concentric tube heat carry-away device provided in the application comprises an outer tube, a tube end fixing cap, and an inner tube. Heat enters through the inner tube, and heat is transmitted to the inner tube. The inner tube lead-in end of the inner tube is made in a horn shape to accelerate entry of the heat. Afterwards, heat flows from the inner tube back into the outer tube, and heat is further transmitted to the outer tube. The heat is subjected to heat dissipation in the cooling space. Due to the arrangement of the heat dissipation grooves inside the outer tube, dissipation of heat is accelerated to thereby increase the heat exchange efficiency. The inner tube and the outer tube performing exchange of heat and also carrying way the heat makes the heat dissipation performance better to ensure normal operation of chips.

### BRIEF DESCRIPTION OF THE DRAWINGS

FIG. 1 is a schematic structure diagram showing a concentric tube heat carry-away device provided in an embodiment of the present invention.

FIG. 2 is a schematic structure diagram showing a concentric tube heat carry-away device provided in an embodiment of the present invention.

FIG. 3 is a schematic structure diagram showing a concentric tube heat carry-away device provided in an embodiment of the present invention.

FIG. 4 is a schematic structure diagram showing a cross section taken along line A-A of FIG. 3.

FIG. 5 is a schematic structure diagram showing an inner tube of a concentric tube heat carry-away device provided in an embodiment of the present invention.

FIG. 6 is a schematic structure diagram showing a concentric tube heat carry-away device provided in another embodiment of the present invention.

FIG. 7 is a schematic diagram showing portion B of FIG. 6 in an enlarged form.

### DETAILED DESCRIPTION OF THE PREFERRED EMBODIMENTS

The following provides a detailed description of an embodiment of the present invention, and illustration of the embodiment is depicted in the attached drawings, in which from beginning to end, the same or similar reference signs indicate the same or similar element or element having the same or similar functionality. The embodiment described below with reference to the attached drawings is only illustrative, aiming to explain the embodiment of the present invention, and not to be construed as limiting to the present invention.

In the description of the embodiment of the present invention, it is understood that the terms “length”, “width”, “up”, “down”, “front”, “rear”, “left”, “right”, “vertical”, “horizontal”, “top”, “bottom”, “inside”, and “outside” indicating directional or positional relationship are interpreted according to the directional or positional relationship depicted in the drawings and are only adopted for easy illustration of the embodiment of the present invention and simplification of the description, and do not indicate or imply a device or element referred to thereby must have a specific direction or must be constructed and operated in a specific direction, and thus, should not be construed as limiting to the present invention.

Further, the terms “first” and “second” are used only for description purposes and are not construed as indicating or implying relative importance or implicitly suggest the number of a technical feature referred to thereby. Thus, a feature defined with “first” and “second” can explicitly or implicitly includes one or more such feature, unless otherwise specifically stated.

In the embodiment of the present invention, unless otherwise explicitly defined and set, the terms “mounting”, “interconnecting”, “connecting”, and “fixing” should be interpreted in a broad sense, such as being fixedly connected or being detachably connected, or being integrated together; or being mechanically connected or electrically connected; or being directly connected or being indirectly connected through an intermediate medium, or interiors of two elements being in communication with each other or two elements being of a relationship of acting on each other. For those having ordinary knowledge of the technical field, the specific meaning of such terms as used in the embodiment of the present invention can be appreciated according to practical conditions.

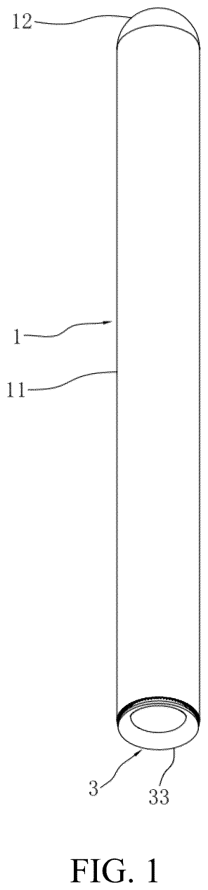

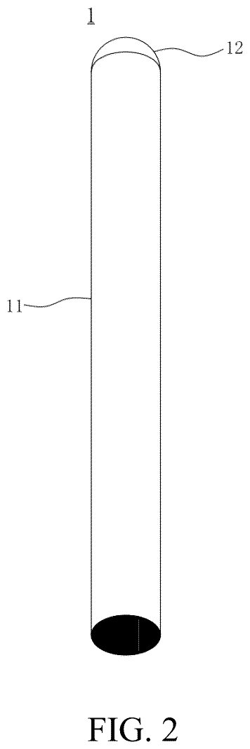

In an embodiment of the present invention, as shown in FIGS. 1-7, a concentric tube heat carry-away device is provided, comprising an outer tube 1, a tube end fixing cap 2, and an inner tube 3. The outer tube 1, the tube end fixing cap 2, and the inner tube 3 are arranged in sequence. Centers of the outer tube 1 and the inner tube 3 are set on a same straight line, and the outer tube 1 and the inner tube 3 are arranged concentrically for easily carrying away heat. Arranged inside the outer tube 1 are heat dissipation grooves 13, and the heat dissipation grooves 13 form heat-dissipating channels, and the heat-dissipating channels accelerates dissipation of heat. The tube end fixing cap 2 is arranged inside the outer tube 1 and is fixedly connected to the outer tube 1. The tube end fixing cap 2 and the outer tube 1 are arranged in a spaced manner for easily carrying away heat. The inner tube 3 is arranged inside the tube end fixing cap 2 and penetrates into the tube end fixing cap 2. The inner tube 3 and the outer tube 1 are arranged to separate from each other and form a cooling space 4. The heat-dissipating channels are arranged in the cooling space 4. The inner tube 3 is in communication with the cooling space 4. In the concentric tube heat carry-away device provided in the application, heat enters through the inner tube 3, and heat is transmitted to the inner tube 3. An inner tube lead-in end 33 of the inner tube 3 is of a horn shape for accelerating entry of heat. Afterwards, the heat flows from the inner tube 3 into the outer tube 1, and heat is further transmitted to the outer tube 1. The heat is subjected to heat dissipation in the cooling space 4. Due to the arrangement of the heat dissipation grooves 13 inside the outer tube 1, dissipation of heat is accelerated to thereby increase the heat exchange efficiency. The inner tube 3 and the outer tube 1 performing exchange of heat and also carrying way the heat makes the heat dissipation performance better to ensure normal operation of chips.

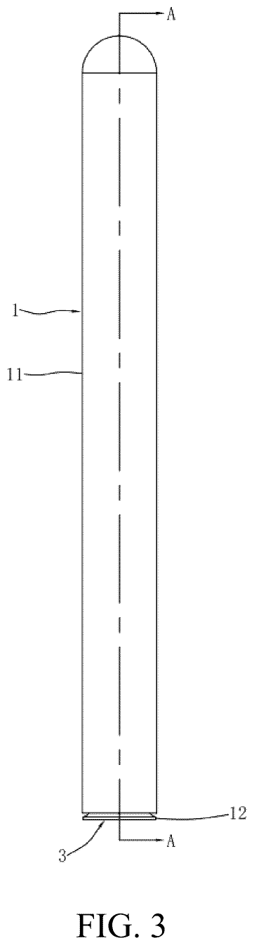

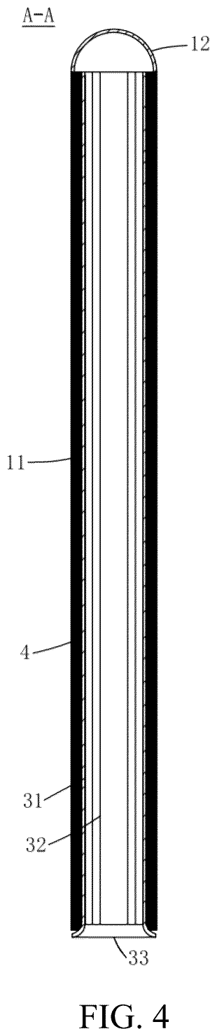

In another embodiment of the present invention, as shown in FIGS. 3 and 4, the outer tube 1 of the concentric tube heat carry-away device comprises an outer tube body 11 and an outer tube flow-return cap 12. The outer tube body 11 and the outer tube flow-return cap 12 are fixedly connected. The outer tube flow-return cap 12 is arranged in a spherical form. Heat enters through the inner tube 3 to then pass through the outer tube flow-return cap 12 to flow into the outer tube body 11, and flowing from the outer tube flow-return cap 12 into the outer tube body 11 carries away the heat.

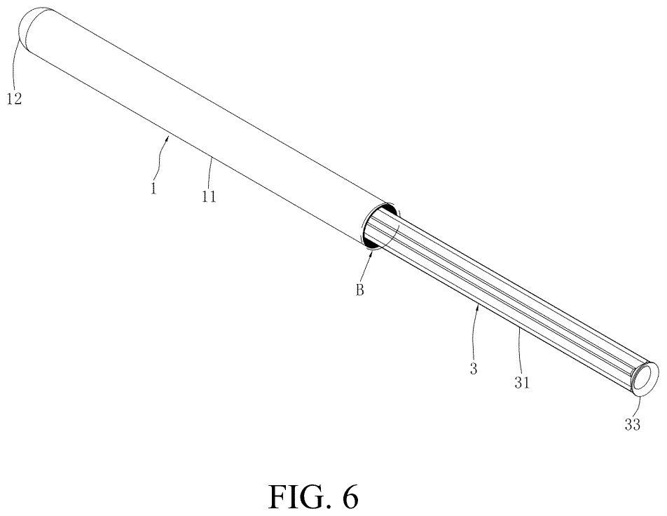

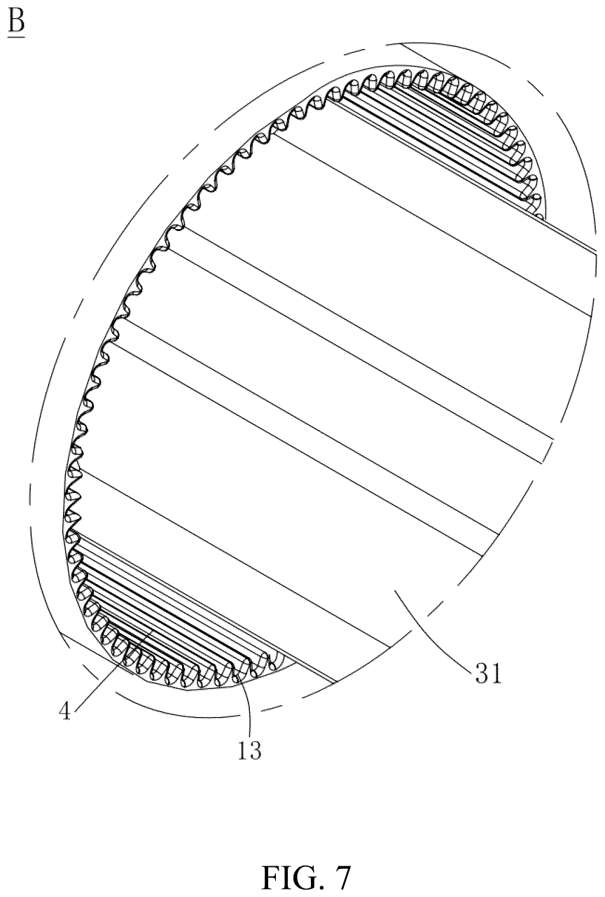

In another embodiment of the present invention, as shown in FIGS. 6 and 7, the heat dissipation grooves 13 of the concentric tube heat carry-away device are arranged as plural ones, and the plural heat dissipation grooves 13 are uniformly arranged inside the outer tube 1. The heat dissipation grooves 13 are sequentially connected and are laid to completely cover the outer tube 1. The heat dissipation grooves 13 are arranged in an arc form. When heat passes through the heat dissipation grooves 13 inside the outer tube 1, dissipation of heat is accelerated to thereby increase the heat dissipation efficiency and make heat dissipation performance better.

In another embodiment of the present invention, as shown in FIG. 7, the plural heat dissipation grooves 13 of the concentric tube heat carry-away device form plural heat-dissipating channels, and the plural heat-dissipating channels are all in communication with the cooling space 4. The heat-dissipating channels accelerates dissipation of heat to thereby increase the heat dissipation efficiency and make heat dissipation performance better.

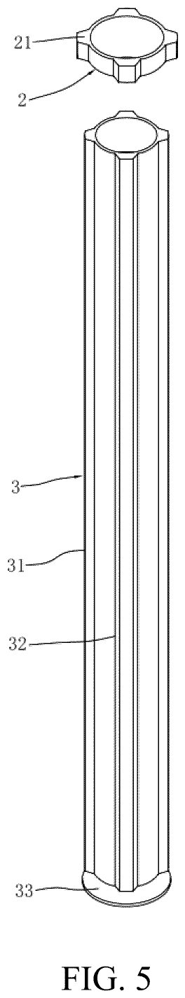

In another embodiment of the present invention, as shown in FIG. 5, the tube end fixing cap 2 of the concentric tube heat carry-away device is formed with positioning notches 21, and the inner tube 3 penetrates into and is fixed in the positioning notches 21.

In another embodiment of the present invention, as shown in FIG. 5, the inner tube 3 of the concentric tube heat carry-away device comprises an inner tube body 31, positioning strips 32, and an inner tube lead-in end 33. A diameter of the inner tube body 31 is smaller than the outer tube body 11. The inner tube body 31 is fixedly connected to the positioning strips 32 and the inner tube lead-in end 3. The positioning strips 32 are arranged as plural ones. The positioning notches 21 correspond, in number, to the positioning strips 32. The positioning strips 32 penetrate into and are fixed in the positioning notches 21. The fixing strips also provide a function of flow splitting to conduct heat out in split flows.

In another embodiment of the present invention, as shown in FIG. 6, the inner tube lead-in end 33 of the concentric tube heat carry-away device is of a horn shape. One end of the inner tube lead-in end 33 is disposed inside the outer tube body 11 and is fixedly connected to the inner tube body 31, while an opposite end extends out of the outer tube body 11. Heat enters through the inner tube body 31 and then passes through the outer tube flow-return cap 12 to flow into the outer tube body 11, and finally discharges out through the inner tube lead-in end 33.

In another embodiment of the present invention, the inner tube lead-in end 33 and the outer tube body 11 of the concentric tube heat carry-away device are arranged to space from each other and form a flow conducting space. The flow conducting space is in communication with the cooling space 4, and heat discharges out through the flow conducting space.

In another embodiment of the present invention, materials of the outer tube 1, the tube end fixing cap 2, and the inner tube 3 of the concentric tube heat carry-away device are all copper to increase the performance of carrying away heat.

In the concentric tube heat carry-away device provided in the application, the outer tube body 11 can adopt a tubular structure that has patterns for fast implementation of heat exchange, such as a sintered tube, a fluted tube, a fiber tube, and a composite tube, and can implement fast heat exchange and realize lowering of temperature through a siphoning effect.

The concentric tube heat carry-away device provided in the application is not only applicable to the field of heat dissipation for chips, but is also applicable to other fields of heat dissipation, such as the field of heat dissipation for data cabinets. The concentric tube heat carry-away device increases heat dissipation efficiency by means of exchange of heat to realize an effect of lowering down temperature.

In the concentric tube heat carry-away device provided in the application, heat enters through the inner tube 3, and heat is transmitted to the inner tube 3. The inner tube lead-in end 33 of the inner tube 3 is made in a horn shape to accelerate entry of the heat. Afterwards, heat flows from the inner tube 3 back into the outer tube 1, and heat is further transmitted to the outer tube 1. The heat is subjected to heat dissipation in the cooling space 4. Due to the arrangement of the heat dissipation grooves 13 inside the outer tube 1, dissipation of heat is accelerated to thereby increase the heat exchange efficiency. The inner tube 3 and the outer tube 1 performing exchange of heat and also carrying way the heat makes the heat dissipation performance better to ensure normal operation of chips.

I claim:

1. A concentric tube heat carry-away device, comprising an outer tube, tube end fixing cap, and an inner tube, wherein the outer tube, the tube end fixing cap, and the inner tube are sequentially arranged, and centers of the outer tube and the inner tube are on a same straight line, heat dissipation grooves being arranged inside the outer tube, the heat dissipation grooves forming heat-dissipating channels, the tube end fixing cap being arranged inside the outer tube and connected to the outer tube, the tube end fixing cap and the outer tube being arranged to space from each other, the inner tube being arranged inside the tube end fixing cap and penetrating into the tube end fixing cap, the inner tube and the outer tube being arranged to space from each other and forming a cooling space, the heat-dissipating channels being arranged in the cooling space, the inner tube being in communication with the cooling space.

2. The concentric tube heat carry-away device according to claim 1, wherein the outer tube comprises an outer tube body and an outer tube flow-return cap, the outer tube body and the outer tube flow-return cap being fixedly connected, the outer tube flow-return cap being arranged in a spherical form.

3. The concentric tube heat carry-away device according to claim 1, wherein the heat dissipation grooves are arranged as plural ones, and the plural heat dissipation grooves are uniformly arranged inside the outer tube, the heat dissipation grooves being sequentially connected and laid to completely cover the outer tube, the heat dissipation grooves being of an arc form.

4. The concentric tube heat carry-away device according to claim 3, wherein the plural heat dissipation grooves for plural heat-dissipating channels, and the heat-dissipating channels are all in communication with the cooling space.

5. The concentric tube heat carry-away device according to claim 2, wherein the tube end fixing cap is formed with positioning notches, and the inner tube penetrates into and is fixed in the positioning notches.

6. The concentric tube heat carry-away device according to claim 5, wherein the inner tube comprises an inner tube body, positioning strips, and an inner tube lead-in end, a diameter of the inner tube body being smaller than the outer tube body, the inner tube body being fixedly connected to the positioning strips and the inner tube lead-in end, the positioning strips being arranged as plural ones, the positioning notches corresponding, in number, to the positioning strips, the positioning strips penetrating into and being fixed in the positioning notches.

7. The concentric tube heat carry-away device according to claim 6, wherein the inner tube lead-in end is of a horn shape, one end of the inner tube lead-in end being disposed inside the outer tube body and fixedly connected to the inner tube body, an opposite end extending out of the outer tube body.

8. The concentric tube heat carry-away device according to claim 6, wherein the inner tube lead-in end and the outer tube body are arranged to space from each other and form a flow conducting space, the flow conducting space being in communication with the cooling space.

9. The concentric tube heat carry-away device according to claim 1, wherein materials of the outer tube, the tube end fixing cap, and the inner tube are all copper.
